(19) United States
(12) Patent Application Publication
(10) Pub. No.: US 2012/0191387 A1
(43) Pub. Date: Jul. 26, 2012

(54) INFORMATION PROCESSING DEVICE, POWER CONSUMPTION CALCULATING SYSTEM AND PROGRAM PRODUCT

(75) Inventors: Shinji Yamanaka, Tokyo (JP); Yuichi Komano, Kanagawa (JP); Toshinari Takahashi, Tokyo (JP); Satoshi Ito, Tokyo (JP)

(73) Assignee: KABUSHIKI KAISHA TOSHIBA, Tokyo (JP)

(21) Appl. No.: 13/356,774

(22) Filed: Jan. 24, 2012

(30) Foreign Application Priority Data
Jan. 25, 2011 (JP) 2011-013422

(51) Int. Cl. G06F 19/00; G01R 21/00

(52) U.S. Cl. 702/62

(57) ABSTRACT

According to one embodiment, an information processing device includes an obtaining unit, a generating unit, and a transmitting unit. The obtaining unit obtains a power consumption of electrical equipment at least once per unit time. The generating unit generates a plurality of pieces of partial information by using a first power consumption and a first value calculated according to a predetermined rule. The generating unit generates a plurality of pieces of partial information by using a second power consumption and the first value. The first power consumption is obtained at a first period. The second power consumption is obtained at a second period different from the first period. The second power consumption is obtained later than the first power consumption. The transmitting unit transmits the pieces of partial information to a plurality of different storage servers, respectively.

### CROSS-REFERENCE TO RELATED APPLICATION

This application is based upon and claims the benefit of priority from Japanese Patent Application No. 2011-013422, filed on Jan. 25, 2011; the entire contents of which are incorporated herein by reference.

### FIELD

Embodiments described herein relate generally to an information processing device, a power consumption calculating system and a program product.

### BACKGROUND

Next-generation power grids (smart grids) have been built in order to stabilize power quality in combining renewable energy, such as sunlight and wind power, with conventional power generation such as nuclear power and thermal power. In a next-generation power grid, a smart meter (referred to as SM) configured to add up power consumption and a home server configured to manage electrical equipment are installed in every home and office. The SM communicates with a meter data management system (MDMS) through the power grid. The MDMS receives power consumption from the SM in every home and office at regular intervals and stores the received data. An energy management system (EMS) performs power control including requesting the SM or a home server in every home and office to reduce power consumption and charging and discharging of storage batteries connected to the power grid on the basis of power consumption of homes and offices gathered in the MDMS.

### BRIEF DESCRIPTION OF THE DRAWINGS

FIG. 1 is a diagram illustrating a configuration of a power consumption calculating system according to a first embodiment;

FIG. 2 is a diagram illustrating a functional configuration of a SM according to the first embodiment;

FIG. 3 is a diagram illustrating functional configurations of first and second storage servers according to the first embodiment;

FIG. 4 is a diagram illustrating a functional configuration of an EMS according to the first embodiment;

FIG. 5 is a diagram illustrating a functional configuration of a billing server according to the first embodiment;

FIG. 6 is a flowchart illustrating procedures of a process performed by the SM according to the first embodiment;

FIG. 7 is a flowchart illustrating procedures of a process performed by the first storage server according to the first embodiment;

FIG. 8 is a flowchart illustrating procedures of a process performed by the first storage server according to the first embodiment;

FIG. 9 is a flowchart illustrating procedures of a process performed by the first storage server according to the first embodiment;

FIG. 10 is a flowchart illustrating procedures of a process performed by the EMS according to the first embodiment;

FIG. 11 is a flowchart illustrating procedures of a process performed by the billing server according to the first embodiment;

FIG. 12 is a diagram illustrating a configuration of a power consumption calculating system according to a second embodiment;

FIG. 13 is a diagram illustrating a functional configuration of a SM according to the second embodiment;

FIG. 14 is a diagram illustrating a functional configuration of a dividing server according to the second embodiment;

FIG. 15 is a flowchart illustrating procedures performed by the SM according to the second embodiment; and

FIG. 16 is a flowchart of procedures of a process performed by the dividing server according to the second embodiment.

### DETAILED DESCRIPTION

In general, according to one embodiment, an information processing device includes an obtaining unit, a generating unit, and a transmitting unit. The obtaining unit obtains a power consumption of electrical equipment at least once per unit time. The generating unit generates a plurality of pieces of partial information by using a first power consumption and a first value calculated according to a predetermined rule. The generating unit generates a plurality of pieces of partial information by using a second power consumption and the first value. The first power consumption is obtained at a first period. The second power consumption is obtained at a second period different from the first period. The second power consumption is obtained later than the first power consumption. The transmitting unit transmits the pieces of partial information generated by using the first power consumption and the pieces of partial information generated by using the second power consumption to a plurality of different storage servers, respectively.

First, an outline of a power consumption calculating system will be described. The power consumption calculating system includes a MDMS connected to SMs described above. A SM adds up power consumption of electrical equipment in every home or office at least once per unit time, and transmits the power consumption to the MDMS. The MDMS stores the power consumption transmitted from the SM. In this case, since the place where electricity is used and the power consumption per unit time may fall under privacy information, the power consumption per unit time is distributed over a plurality of pieces of partial information and stored in the MDMS. The privacy information is information by which a preference or an activity of an individual or an organization is identified. The privacy information also includes information that identifies an individual or an organization itself. The privacy information also includes information by which a trend in preference or activities of an individual or an organization is identified even if the individual or the organization itself is not identified. The determination whether the power consumption per unit time falls under the privacy information may be made in advance or may be dynamically made. Moreover, the power consumption may be distributed over pieces of partial information and stored in the MDMS even when the power consumption per unit time and the place where electricity is used do not fall under the privacy information.

For example, an application for billing processing in proportion to power consumption requires a correct value of the power consumption of every home or office as an input thereto. In this case, a calculation using a value calculated according to a predetermined rule is employed as a method for distributing the power consumption over pieces of partial information so that a decoded result of a correct value of a total (total power consumption) that is a sum of power consumption data of the home or office can be obtained without decoding the power consumption by the MDMS.

In the embodiments described below, description is made on examples in which power consumption of every home per first unit time is hidden, and an EMS to which total power consumption of a plurality of homes per second unit time is input and a billing server to which power consumption of every home per third unit time is input are used as application servers. While the power consumption of every home is hidden in the embodiments, the power consumption to be hidden is not limited to that of every home, and power consumption of any range or unit that consumes power, for which a smart meter performs adding up, may be hidden. In this case, “home” used herein can be replaced by “range (unit) of adding up”.

### First Embodiment

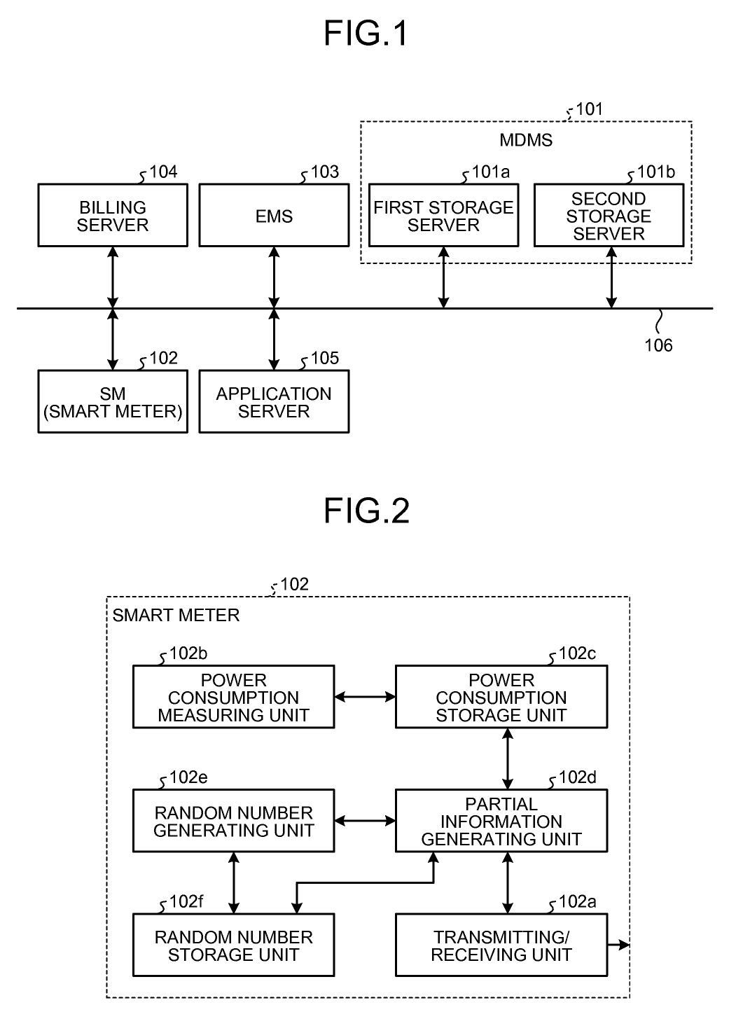

FIG. 1 is a diagram illustrating a configuration of a power consumption calculating system according to this embodiment. As illustrated in FIG. 1, the power consumption calculating system has a configuration in which a meter data management system (MDMS) 101, a smart meter (SM) 102, an energy management system (EMS) 103, a billing server 104 and an application server 105 are connected through a network 106. Although only one smart meter 102 is illustrated for simplification of the drawing, a plurality of SMs 102 can be connected in the power consumption calculating system. The network 106 is, for example, a local area network (LAN), an intranet, an Ethernet (registered trademark), the Internet or the like. The MDMS 101 is a system for gathering power consumption of respective homes via the network 106 and includes a first storage server 101a and a second storage server 101b. The SM 102 is a power meter that is installed in home and configured to add up power consumption of electrical equipment used at home.

It is assumed here that identification information (referred to as home identification information) is assigned to the SM 102 for identifying the SM 102 for each home, and the SM 102 stores the home identification information assigned to the home. It is also assumed here that each of the MDMS 101, the EMS 103 and the billing server 104 store all the home identification information of the SMs 102 connected to the power consumption calculating system.

An outline of a basic functional configuration implemented in the power consumption calculating system having such configuration will be described. A calculation using power consumption added up by the SM 102 and a value calculated according to a predetermined rule is performed to generate a plurality of pieces of first partial information. Typically, the original power consumption can be restored by integrating at least k (k≦n) pieces of first partial information out of n pieces of first partial information into which the first partial information is divided. The predetermined rule is a rule (method) for generating a value that cannot be predicted by the MDMS 101, the EMS 103 and the billing server 104. For example, the predetermined rule may be a method using the middle-square method, a linear congruential method, a linear feedback shift register, a Mersenne twister or the like. A value calculated according to the predetermined rule is a random number in this embodiment. A case where n=2 and k=2 are satisfied will be described below. However, n=3 and k=3 (using two random numbers and also a third storage server) may be satisfied or n=3 and k=2 (EMS 103 and billing processing are performed using two out of three pieces of first partial information by a secret sharing scheme) may be satisfied, for example. In this embodiment, the SM 102 generates two pieces of partial information and transmits one of the pieces to the first storage server 101a and the other piece to the second storage server 101b. Note that the home identification information and the power consumption are associated in the information added up by the SM 102, and the SM 102 transmits the associated information together with each of the pieces of partial information to the first storage server 101a and the second storage server 101b. The first storage server 101a and the second storage server 101b each calculate second partial information and third partial information according to purposes of applications without restoring the original power consumption from the pieces of first partial information. The second partial information includes information that is obtained by calculating all the pieces of first partial information per the first unit time so that the EMS 103 performs power control as an application. The second partial information is information for calculating an input to the application such as a total of power consumption per the first unit time of homes or offices in a certain region. The third partial information is information that is obtained by calculating all the pieces of first partial information so that the billing server 104 performs billing processing as an application. The third partial information is information for calculating an input to an application such as a total of power consumption of individual home or office. Different units are used for calculation of the first partial information, the second partial information and the third partial information. The first partial information used for calculating the second partial information and the third partial information may include a plurality of pieces of first partial information calculated from the power consumption added up by different SMs 102, or include a plurality of pieces of first partial information calculated from the power consumption added up by a SM 102 at different times. The first storage server 101a and the second storage server 101b transmit the second partial information to the EMS 103 and the third partial information to the billing server 104. Then, the EMS 103 and the billing server 104 each restore an input to an application from a plurality of pieces of second partial information or third partial information that are received, and perform processing of the application.

In addition to the basic functional configuration as described above, the SM 102 is further configured to use the same value a plurality of times for the calculation of the pieces of first partial information as a value calculated according to the predetermined rule in this embodiment. In addition, the SM 102 randomly determines destinations of the pieces of first partial information. Detailed configuration thereof will be described later.

Hardware configurations of the first storage server 101a, the second storage server 101b, the SM 102, the EMS 103, the billing server 104 and the application server 105 will be described here. Each of these information processing devices includes a control unit such as a central processing unit (CPU) configured to control the entire information processing device, a main storage unit such as a read only memory (ROM) and a random access memory (RAM) configured to store various data and various programs, an auxiliary storage unit such as a hard disk drive (HDD) and a compact disk (CD) drive configured to store various data and various programs, and a bus that connects these units. Each information processing device has a hardware configuration using a common computer system. The first storage server 101a, the second storage server 101b, the SM 102, the EMS 103 and the billing server 104 each further include a communication interface (I/F) for communication via the network 106. Note that cryptographic communication may be used when the devices communicate through the network 106 for keeping the communication secret or for verification. However, description of configuration for such cryptographic communication of each information processing device is not provided for simplification.

Next, various functions implemented in each of the first storage server 101a, the second storage server 101b, the SM 102, the EMS 103 and the billing server 104 will be described. First, a functional configuration of the SM 102 will be described referring to FIG. 2. The SM 102 includes a transmitting/receiving unit 102a, a power consumption measuring unit 102b, a power consumption storage unit 102c, a partial information generating unit 102d, a random number generating unit 102e and a random number storage unit 102f. The functions of the transmitting/receiving unit 102a are implemented by the communication I/F of the SM 102 and by executing various programs stored in the main storage unit and the auxiliary storage unit by the CPU of the SM 102. The functions of the power consumption measuring unit 102b, the partial information generating unit 102d and the random number generating unit 102e are implemented by executing various programs stored in the main storage unit and the auxiliary storage unit by the CPU of the SM 102. The power consumption storage unit 102c and the random number storage unit 102f are storage areas reserved in the auxiliary storage unit, for example, of the SM 102. The home identification information described above is stored in the auxiliary storage unit, for example.

The power consumption measuring unit 102b obtains power consumption by adding up power consumption z_{i,j} of electrical equipment connected to a power line in a home or an office where the SM 102 is installed at least once per the first unit time. The power consumption measuring unit 102b then stores the added up power consumption in the power consumption storage unit 102c. The first unit time refers to a time interval at which the SM 102 adds up the power consumption. The first unit time is a time interval of fifteen minutes, for example. In addition, i represents an index corresponding to a home, and j represents an index corresponding to an order (date, time, etc.) of the first unit time. The power consumption storage unit 102c stores the power consumption z_{i,j} added up by the power consumption measuring unit 102b.

The random number generating unit 102e is configured to calculate a value according to a predetermined rule under the control of the partial information generating unit 102d. In this embodiment, the random number generating unit 102e generates a random number r according to a predetermined random number generating rule. The random number storage unit 102f stores the random number r generated by the random number generating unit 102e under the control of the partial information generating unit 102d. The random number r is deleted after being used a plurality of times by the partial information generating unit 102d.

The partial information generating unit 102d generates two pieces of first partial information by calculation using the power consumption z_{i,j} and the random number stored in the random number storage unit 102f or the random number generated by the random number generating unit 102e each time the power consumption z_{i,j} is added up by the power consumption measuring unit 102b and stored in the power consumption storage unit 102c. Specifically, if a random number is stored in the random number storage unit 102f, the partial information generating unit 102d generates two pieces of first partial information by calculation using the random number and the power consumption z_{i,j} stored in the power consumption storage unit 102c, and deletes the random number from the random number storage unit 102f. If no random number is stored in the random number storage unit 102f, on the other hand, the partial information generating unit 102d controls the random number generating unit 102e to generate a random number, generates two pieces of first partial information by calculation using the random number and the power consumption z_{i,j} stored in the power consumption storage unit 102c, and then stores the random number in the random number storage unit 102f. In this manner, the partial information generating unit 102d generates two pieces of first partial information by using the power consumption added up by the power consumption measuring unit 102b and a random number, and thereafter generates two new pieces of first partial information by using power consumption newly added up by the power consumption measuring unit 102b and this random number. In other words, for calculating two pieces of first partial information at least once per the first unit time, the partial information generating unit 102d uses the same random number for calculation of the pieces of first partial information at each of a first period and a second period. The length of the first period is the first unit time. The length of the second period is the first unit time.

The two pieces of first partial information are respectively calculated by the following equations (1) and (2), for example, where the two pieces of first partial information are represented by z_{i,j,1} and Z_{i,j,2}, respectively. A parameter α is a large number that is the same for the SM 102, the first storage server 101a, the second storage server 101b, the EMS 103, the billing server 104 and the application server 105.

z_{fi,j,1]=r mod α (1)

z_{—}{i,j,2}=z_{—}{i,j}−r mod α (2)

The partial information generating unit 102d also randomly determines the destination of at least one of the generated two pieces of first partial information z_{i,j,1} and z_{i,j,2} to be the first storage server 101a or the second storage server 101b. For example, the partial information generating unit 102d may control the random number generating unit 102e to generate a random number equal to or larger than “0” and smaller than 1. If the generated random number is smaller than “0.5”, the partial information generating unit 102d may determine the first storage server 101a to be the destination of one piece of first partial information z_{i,j,1} and, as a result, determine the second storage server 101b different from the first storage server 101a to be the destination of the other piece of first partial information z_{i,j,2}. If the generated random number is equal to or larger than “0.5”, the partial information generating unit 102d may determine the first storage server 101a to be the destination of one piece of first partial information z_{i,j,2} and, as a result, determine the second storage server 101b different from the first storage server 101a to be the destination of the other piece of first partial information z_{i,j,1}. The determination may be made according to a predetermined method instead of a random manner.

The transmitting/receiving unit 102a is configured to control communication with other information processing devices such as the first storage server 101a and the second storage server 101b. In particular, in this embodiment, the transmitting/receiving unit 102a transmits one of the two pieces of first partial information generated by the partial information generating unit 102d, which is the one for which the destination is determined to be the first storage server 101a, together with the home identification information to the first storage server 101a, transmits the other piece of first partial information together with the home identification information to the second storage server 101b, and receives a power control command from the EMS 103, which will be described later.

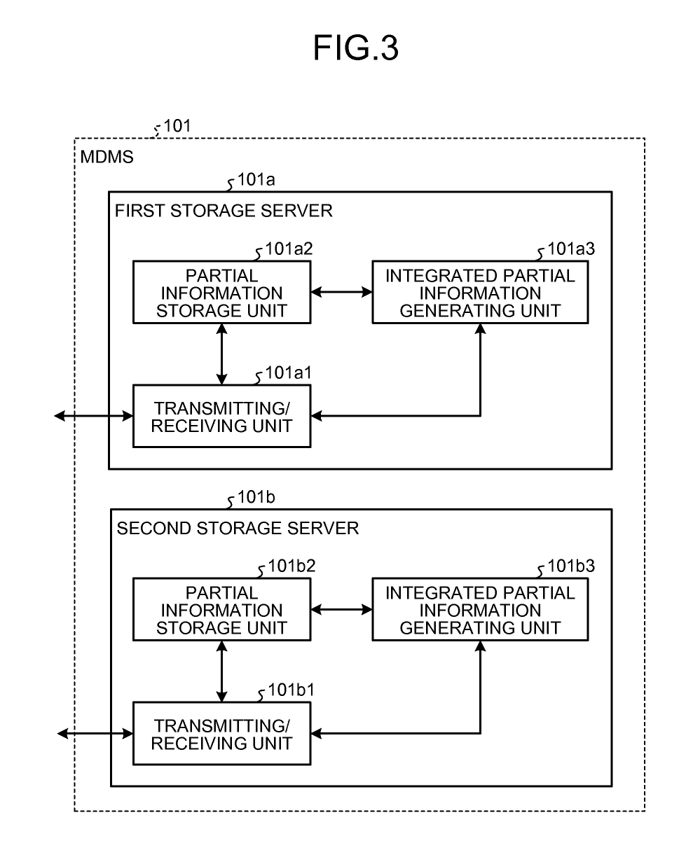

Next, functional configurations of the first storage server 101a and the second storage server 101b will be described referring to FIG. 3. The first storage server 101a includes a transmitting/receiving unit 101a1, a partial information storage unit 101a2 and an integrated partial information generating unit 101a3. The functions of the transmitting/receiving unit 101a1 are implemented by the communication I/F of the first storage server 101a and by executing various programs stored in the main storage unit and the auxiliary storage unit by the CPU of the first storage server 101a. The functions of the integrated partial information generating unit 101a3 are implemented by executing various programs stored in the main storage unit and the auxiliary storage unit by the CPU of the first storage server 101a. The partial information storage unit 101a2 is a storage area reserved in the auxiliary storage unit, for example, of the first storage server 101a. The second storage server 101b includes a transmitting/receiving unit 101b1, a partial information storage unit 101b2 and an integrated partial information generating unit 101b3. The functions of the transmitting/receiving unit 101b1 are implemented by the communication I/F of the second storage server 101b and by executing various programs stored in the main storage unit and the auxiliary storage unit by the CPU of the second storage server 101b. The functions of the integrated partial information generating unit 101b3 are implemented by executing various programs stored in the main storage unit and the auxiliary storage unit by the CPU of the second storage server 101b. The partial information storage unit 101b2 is a storage area reserved in the auxiliary storage unit, for example, of the second storage server 101b.

Since the functional configurations of the first storage server 101a and the second storage server 101b are the same, the functional configuration of the first storage server 101a will be described in the following and the description of the functional configuration of the second storage server 101b is omitted. The transmitting/receiving unit 101a1 is configured to control communication with other information processing devices such as the SM 102, the EMS 103 and the billing server 104. In particular, in this embodiment, the transmitting/receiving unit 101a1 receives the first partial information and the home identification information from the SM 102 at least once per the first unit time, receives a transmission request requesting transmission of total power consumption per the first unit time within the second unit time of a certain region from the EMS 103 at every second unit time, receives a transmission request requesting transmission of total power consumption within the third unit time of each home from the billing server 104 at every third unit time, transmits second partial information calculated by the integrated partial information generating unit 101a3, which will be described later, to the EMS 103 in response to a transmission request from the EMS 103, and transmits third partial information generated by the integrated partial information generating unit 101a3 to the billing server 104 in response to a transmission request from the billing server 104. The second unit time refers to a time interval at which the EMS 103, which will be described later, calculates the total power consumption to control the power grid. The second unit time is a time interval of thirty minutes, for example. The third unit time refers to a time interval at which the billing server 104, which will be described later, calculates the total power consumption of a certain home to perform billing. The third unit time is a time interval of one month, for example.

The partial information storage unit 101a2 stores the first partial information and the home identification information received by the transmitting/receiving unit 101a1 at least once per the first unit time from the SM 102 in association with time (referred to as power consumption time).

When the transmitting/receiving unit 101a1 has received a transmission request from the EMS 103, the integrated partial information generating unit 101a3 reads out one piece of first partial information, which is associated with a power consumption time in units of the first unit time included in the second unit time, out of pieces of first partial information stored in the partial information storage unit 101a2 respectively in association with home identification information of all or some of homes belonging to a region in which the MDMS 101 controls the SMs thereof. The integrated partial information generating unit 101a3 then adds up the pieces of first partial information at every first unit time, and generates the second partial information containing all the pieces of first partial information added up at every first unit time. By adding the thus obtained second partial information and second partial information generated by the second storage server 101b, total power consumption per the first unit time within the second unit time of all or some homes belonging to a certain region is restored. For example, the second partial information a_{—}{2,1} generated by the first storage server 101a is expressed by the following equation (3) where the power consumption time in units of the first unit time included in the second unit time is represented by j1, j2, . . . , jN, and the sum of the first partial information per the first unit time of all or some of homes belonging to a certain region is represented by a_{—}{2,1}ⱼₘ (m=1, . . . , N).

a_{—}{2,1}=(a_{—}{2,1}ⱼ₁, a_{—}{2,1}ⱼ₂, . . . , a_{—}{2,1}_{jN}) (3)

When the transmitting/receiving unit 101a1 has received a transmission request from the billing server 104, the integrated partial information generating unit 101a3 reads out one piece of first partial information, which is associated with a power consumption time in units of the first unit time included in the third unit time, out of pieces of first partial information stored in the partial information storage unit 101a2 each in association with home identification information of each home. The integrated partial information generating unit 101a3 then adds up the pieces of first partial information for each of home identification information to generate the third partial information for each of home identification information. By adding the thus obtained third partial information and third partial information for each of home identification information generated by the second storage server 101b, total power consumption per the third unit time for each home is restored. For example, the third information a_{—}{3,i,1} generated by the first storage server 101a is expressed by the following equation (4) where the first partial information per the first unit time for a home with home identification information i is represented by z_i,j,1} and the power consumption time in units of the first unit time included in the second unit time is represented by j1, j2, . . . , jN.

a_{—}{3, i,1}=Σ_{j=j1, j2, . . . , jN} z_{i,j,1} (4)

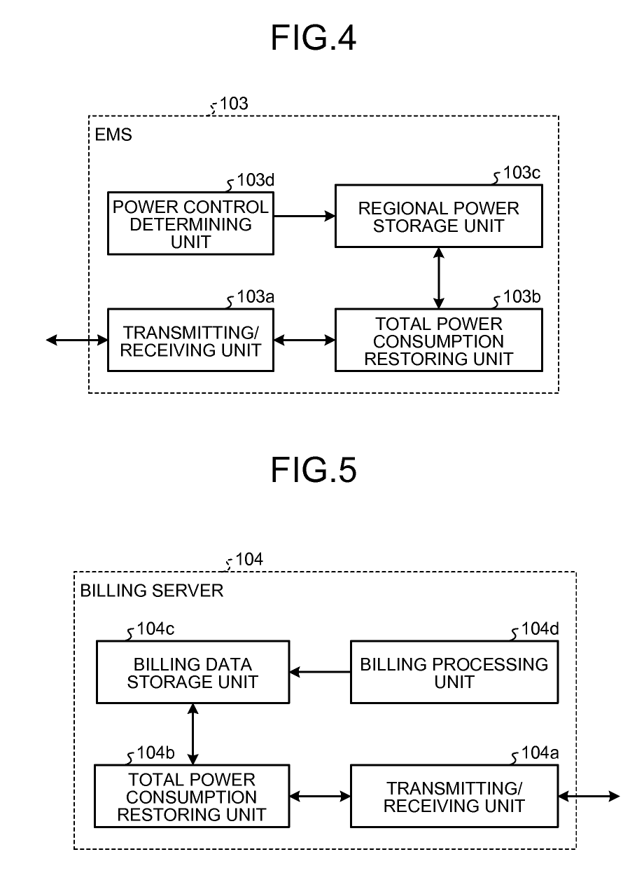

Next, a functional configuration of the EMS 103 will be described referring to FIG. 4. As illustrated in FIG. 4, the EMS 103 includes a transmitting/receiving unit 103a, a total power consumption restoring unit 103b, a regional power storage unit 103c and a power control determining unit 103d. The functions of the transmitting/receiving unit 103a are implemented by the communication I/F of the EMS 103 and by executing various programs stored in the main storage unit and the auxiliary storage unit by the CPU of the EMS 103. The functions of the total power consumption restoring unit 103b and the power control determining unit 103d are implemented by executing various programs stored in the main storage unit and the auxiliary storage unit by the CPU of the EMS 103. The regional power storage unit 103c is a storage area reserved in the auxiliary storage unit, for example, of the EMS 103.

The transmitting/receiving unit 103a is configured to control communication with other information processing devices such as the first storage server 101a and the second storage server 101b. In particular, in this embodiment, the transmitting/receiving unit 103a transmits a transmission request requesting transmission of total power consumption per the first unit time within the second unit time of all or some of homes belonging to a certain region to the first storage server 101a and the second storage server 101b at every second unit time, receives the second partial information transmitted from the first storage server 101a and the second storage server 101b, and transmits a power control command to the SM 102 under the control of the power control determining unit 103d, which will be described later.

The total power consumption restoring unit 103b integrates the pieces of second partial information received by the transmitting/receiving unit 103a from the first storage server 101a and the second storage server 101b to restore total power consumption per the first unit time within the second unit time of all or some of homes belonging to a certain region. For example, the total power consumption a_{—}{4, i} per the first unit time within the second unit time of all or some of homes belonging to a certain region is restored as a result of adding the second partial information received from the first storage server 101a and the second partial information received from the second storage server 101b in units of the first unit time by the following equation (5), where the power consumption time in units of the first unit time included in the second unit time is represented by j1, j2, . . . , jN, the sum of the first partial information per the first unit time of all or some of homes belonging to a certain region is represented by a_{—}{2,1}ⱼₘ (m=1, . . . , N), the second partial information received from the first storage server 101a is represented by (a_{—}{2,1}ⱼ₁, a_{—}{2,1}ⱼ₂, . . . , a_{—}{2,1}_{jN}), and the second partial information received from the second storage server 101b is represented by (a_{—}{2,2}ⱼ₁, a_{—}{2,2}ⱼ₂, . . . , a_{—}{2,2}_{jN}).

a_{—}{4, i}=(a_{—}{2,1}ⱼ₁, a_{—}{2,1}ⱼ₂, . . . , a_{—}{2,1}_{jN})+(a_{—}{2,2}ⱼ₁, a_{—}{2,2}ⱼ₂, . . . , a_{—}{2,2}_{jN})mod α (5)

The regional power storage unit 103c stores total power consumption per the first unit time within the second unit time of all or some of homes belonging to a certain region that is restored by the total power consumption restoring unit 103b. The power control determining unit 103d determines whether or not power control is to be performed on the basis of the total power consumption restored by the total power consumption restoring unit 103b. The power control refers, for example, to suppressing power consumption at each home when the total power consumption per the first unit time within the second unit time exceeds an upper threshold, and charging storage batteries when the total power consumption is lower than a lower threshold. If the power control determining unit 103d determines to perform power control and to suppress the power consumption at each home, the power control determining unit 103d makes the transmitting/receiving unit 103a transmit a power control command requesting suppression of power consumption to the SM 102.

Next, a functional configuration of the billing server 104 will be described referring to FIG. 5. As illustrated in FIG. 5, the billing server 104 includes a transmitting/receiving unit 104a, a total power consumption restoring unit 104b, a billing data storage unit 104c and a billing processing unit 104d. The functions of the transmitting/receiving unit 104a are implemented by the communication I/F of the billing server 104 and by executing various programs stored in the main storage unit and the auxiliary storage unit by the CPU of the billing server 104. The functions of the total power consumption restoring unit 104b and the billing processing unit 104d are implemented by executing various programs stored in the main storage unit and the auxiliary storage unit by the CPU of the billing server 104. The billing data storage unit 104c is a storage area reserved in the auxiliary storage unit, for example, of the billing server 104.

The transmitting/receiving unit 104a is configured to control communication with other information processing devices such as the first storage server 101a and the second storage server 101b. In particular, in this embodiment, the transmitting/receiving unit 104a transmits a transmission request requesting transmission of total power consumption within the third unit time for each home to the first storage server 101a and the second storage server 101b at every third unit time, and receives the third partial information transmitted from the first storage server 101a and the second storage server 101b.

The total power consumption restoring unit 104b integrates the pieces of third partial information received by the transmitting/receiving unit 104a from the first storage server 101a and the second storage server 101b for each home identification information to restore total power consumption within the third unit time for each home. For example, the total power consumption a_{—}{5,i} for a home with home identification information i is restored as a result of adding the third partial information received from the first storage server 101a and the third partial information received from the second storage server 101b by the following equation (6), where the third partial information received from the first storage server 101a is represented by a_{—}{3,i,1} and the third partial information received from the second storage server 101b is represented by a_{—}{3,i,2}.

i a_{—}{5,i}=a_{—}{3,i,1}+a_{—}{3,i,2} mod α (6)

The billing data storage unit 104c stores total power consumption within the third unit time for each home that is restored by the total power consumption restoring unit 104b. The billing processing unit 104d makes the transmitting/receiving unit 104a transmit a transmission request requesting the first storage server 101a and the second storage server 101b to transmit total power consumption within the third unit time for each home at every third unit time, and performs billing processing on the basis of the total power consumption within the third unit time for each home restored by the total power consumption restoring unit 104b.

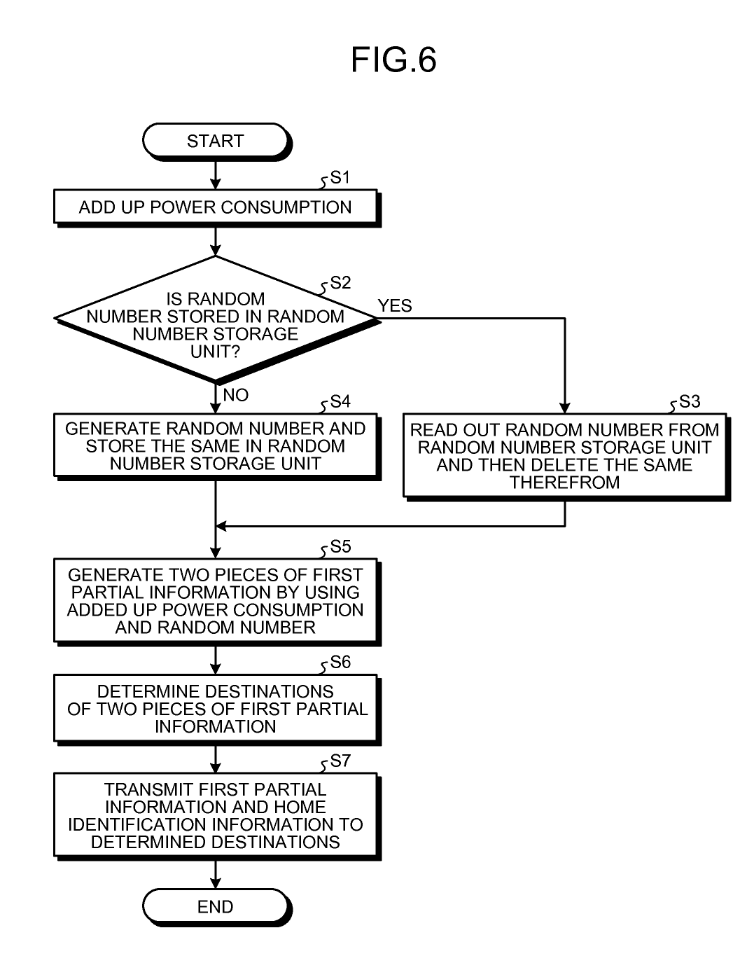

Next, procedures of processes performed by the power consumption calculating system according to this embodiment will be described. First, procedures for transmitting first partial information by the SM 102 to the first storage server 101a and the second storage server 101b will be described with reference to FIG. 6. The SM 102 adds up power consumption z_{i,j} of power consumed in a home i at least once per the first unit time and stores the addition result to the power consumption storage unit 102c (step S1). The SM 102 then determines whether or not a random number is stored in the random number storage unit 102f (step S2). If a random number is stored in the random number storage unit 102f (Yes in step S2), this means that a random number used for generating first partial information in previous step S5 is stored in the random number storing unit 102f. In this embodiment, the same random number as that used in previous step S5 is used here for generating first partial information in step S5 of this time. The SM 102 thus reads out the random number (r) from the random number storage unit 102f, and then deletes the random number r from the random number storage unit 102f (step S3). On the other hand, if no random number is stored in the random number storage unit 102f (No in step S2), the SM 102 generates a random number r and stores the random number r in the random number storage unit 102f (step S4). In this case, the random number r stored in the random number storage unit 102f will be used for generating first partial information in step S5 of the next time. The SM 102 generates two pieces of first partial information z_{i,j,1} and z_{i,j,2} by calculation of the equations (1) and (2) using the power consumption added up in step S2 and the random number r read in step S3 or the random number generated in step S4 (step S5).

The SM 102 then determines the destination of each of the two pieces of partial information z_{i,j,1} and z_{i,j,2} randomly or in a predetermined manner to be the first storage server 101a or the second storage server 101b (step S6). In this case, for example, the SM 102 determines the destination of one piece of first partial information z_{i,j,1} to be the first storage server 101a and, as a result, the destination of the other piece of first partial information z_{i,j,2} to be the second storage server 101b different from the first storage server 101a. Next, the SM 102 transmits the pieces of first partial information z_{i,j,1} and z_{i,j,2} to the destinations determined in step S6, respectively (step S7). For example, the SM 102 transmits the first partial information z_{i,j,1} and home identification information stored in the auxiliary storage unit to the first storage server 101a and transmits the first partial information z_{i,j,2} and the home identification information stored in the auxiliary storage unit to the second storage server 101b.

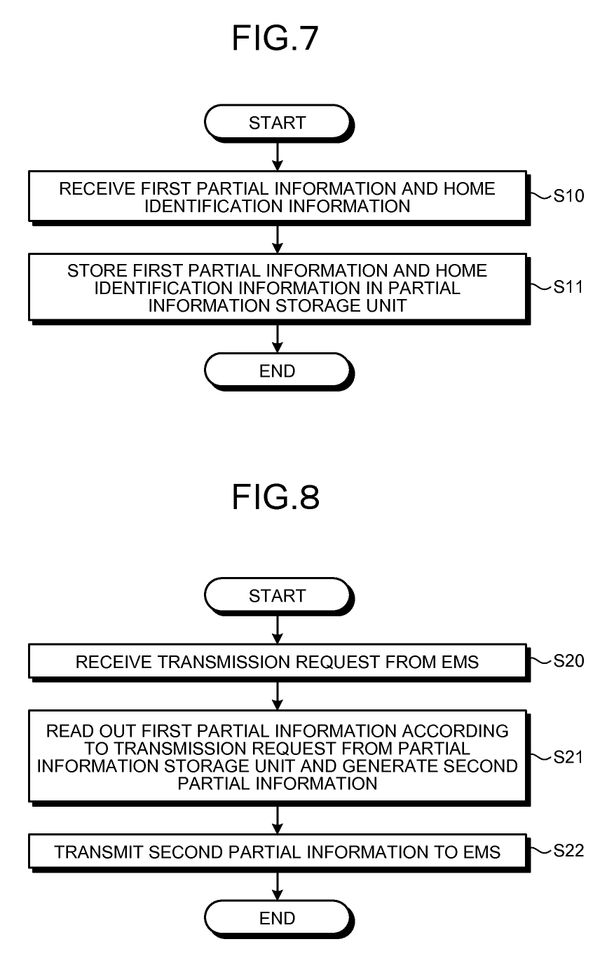

Next, procedures of a process of receiving the first partial information from the SM 102 by the first storage server 101a will be described with reference to FIG. 7. Since procedures of a process of receiving the first partial information from the SM 102 by the second storage server 101b are the same as those by the first storage server 101a, the description thereof is omitted. Upon receiving either of the first partial information z_{i,j,1} or z _{i,j,2} and the home identification information from the SM 102 of each home at least once per the first unit time (step S10), the first storage server 101a stores the received information in the partial information storage unit 101a2 (step S11).

Next, procedures of a process of transmitting second partial information to the EMS 103 by the first storage server 101a in response to a transmission request from the EMS 103 will be described with reference to FIG. 8. Since procedures of a process of transmitting second partial information to the EMS 103 by the second storage server 101b in response to a transmission request from the EMS 103 are the same as those by the first storage server 101a, the description thereof is omitted. Upon receiving a transmission request requesting transmission of total power consumption per the first unit time within the second unit time of a certain region from the EMS 103 (step S20), the first storage server 101a reads out a piece of the first partial information associated with the power consumption time in units of the first unit time included in the second unit time out of pieces of first partial information stored in the partial information storage unit 101a2 each in association with home identification information of all or some of homes belonging to a certain region, adds up pieces of first partial information at every first unit time, and generates second partial information including all the pieces added up at every first unit time by the equation (3), for example (step S21). The first storage server 101a then transmits the second partial information generated in step S21 to the EMS 103 (step S22). The first storage server 101a performs the above-described process each time the first storage server 101a receives a transmission request from the EMS 103 at every second unit time.

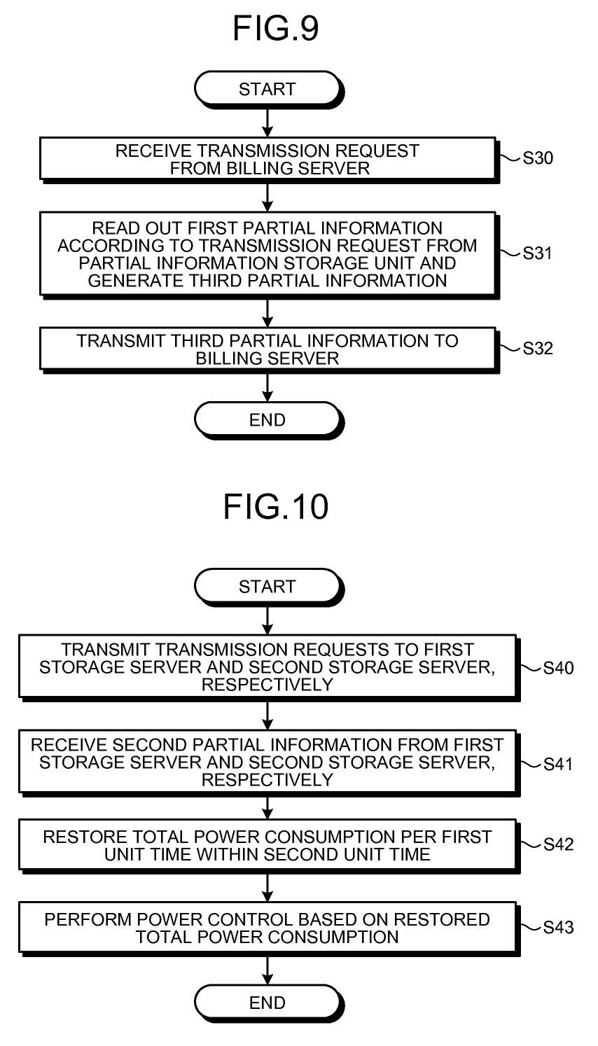

Next, procedures of a process of transmitting third partial information to the billing server 104 by the first storage server 101a in response to a transmission request from the billing server 104 will be described with reference to FIG. 9. Since procedures of a process of transmitting third partial information to the billing server 104 by the second storage server 101b in response to a transmission request from the billing server 104 are the same as those by the first storage server 101a, the description thereof is omitted. Upon receiving a transmission request requesting transmission of total power consumption within the third unit time for each home from the billing server 104 (step S30), the first storage server 101a reads out a piece of first partial information associated with power consumption time in units of the first unit time included in the third unit time out of pieces of first partial information stored in the partial information storage unit 101a2 each in association with home identification information for each home, and adds up the read pieces of first partial information for each home identification information (refer, for example, to the equation (4)) to generate the third partial information for each home identification information (step S31). The first storage server 101a then transmits the third partial information for each home identification information generated in step S31 to the billing server 104 (step S32). The first storage server 101a performs the above-described process each time the first storage server 101a receives a transmission request from the billing server 104 at every third unit time.

Next, procedures of a process of transmitting a transmission request by the EMS 103 to perform power control will be described with reference to FIG. 10. The EMS 103 transmits transmission requests requesting transmission of total power consumption within the second unit time of a certain region to the first storage server 101a and the second storage server 101b, respectively (step S40). When pieces of second partial information are transmitted from the first storage server 101a and the second storage server 101b in response to the transmission request, the EMS 103 receives the transmitted pieces of second partial information (step S41). The EMS 103 then integrates the pieces of second partial information received in step S41 (refer, for example, to the equation (5)) to restore total power consumption per the first unit time within the second unit time of all or some of homes belonging to a certain region (step S42), and stores the restored total power consumption in the regional power storage unit 103c. The EMS 103 then performs power control on the basis of the total power consumption restored in step S42 (step S43).

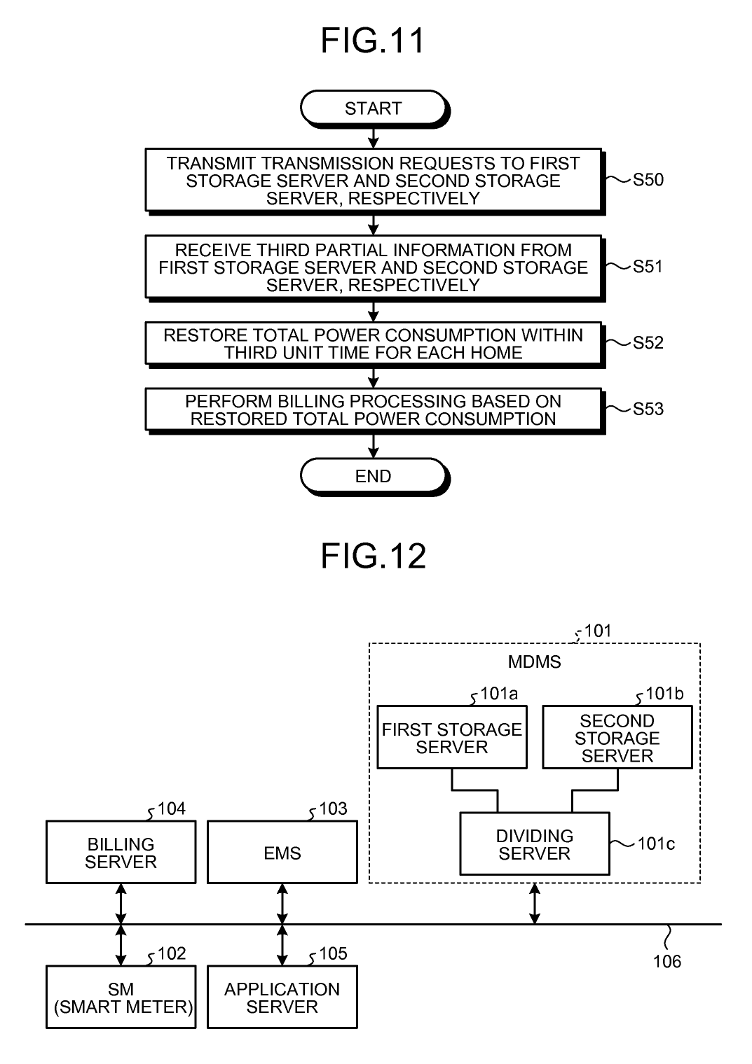

Next, procedures of a process of transmitting a transmission request to perform billing processing by the billing server 104 will be described with reference to FIG. 11. The billing server 104 transmits transmission requests requesting transmission of total power consumption within the third unit time for each home to the first storage server 101a and the second storage server 101b, respectively, at every third unit time (step S50). When pieces of third partial information for each home identification information are transmitted from the first storage server 101a and the second storage server 101b in response to the transmission requests, the billing server 104 receives the pieces of third partial information (step S51). The billing server 104 then integrates the pieces of third partial information received in step S51 (refer, for example, to the equation (6)) to restore total power consumption within the third unit time for each home (step S52) and stores the restored total power consumption in the billing data storage unit 104c. The billing server 104 then performs billing processing on the basis of the total power consumption restored in step S52 (step S53).

In this embodiment, as described above, the power consumption per the first unit time of each home is distributed into a plurality of pieces of first partial information by calculation using a value calculated according to a predetermined rule by the SM 102. Even if one of the pieces of first partial information resulting from the distribution is obtained, the original power consumption before the calculation cannot be restored. It is therefore possible to avoid the risk of leakage of the power consumption of each home even to a manager of the MDMS 101 including the first storage server 101a and the second storage server 101b and an unauthorized user who has broken into the MDMS 101. Thus, the manager of the MDMS 101 and the unauthorized user who has broken into the MDMS 101 cannot see the power consumption per the first unit time of each home and cannot guess whether or not there is someone at home or activities of people therein in association with time. The privacy of each home can therefore be protected.

In this embodiment, the EMS 103 that calculates total power consumption of all or some of homes at the first unit time for performing power control is employed as an application server. The first storage server 101a and the second storage server 101b each calculate total power consumption per the first unit time within the second unit time for all or some of homes in a certain region from the first partial information of the power consumption per the first unit time of each home, and transmit the calculation result to the EMS 103. As a result, the EMS 103 can know the total power consumption per the first unit time of all or some of the homes in the certain region but cannot calculate the power consumption at the first unit time of each home. The privacy of each home can therefore be protected.

Furthermore, the billing server 104 that calculates the total power consumption of each home at the third unit time for performing billing processing of each home is employed as an application server. The first storage server 101a and the second storage server 101b each calculate total power consumption within the third unit time from the first partial information of the power consumption at the first unit time of each home, and transmit the calculation result to the billing server 104. As a result, the billing server 104 can restore the total power consumption at the third unit time of each home but cannot calculate the power consumption at the first unit time of each home. The privacy of each home can therefore be protected.

As described above, according to this embodiment, the total power consumption can be calculated while hiding each power consumption added up by each SM 102 at the MDMS 101 to protect the privacy.

### Second Embodiment

Next, a second embodiment of the information processing device, the power consumption calculating system and the program will be described. Parts that are the same as those in the first embodiment described above will be described using the same reference numerals or description thereof will not be repeated.

In the first embodiment described above, the SM 102 performs calculation using the power consumption added up by the SM 102 and a value calculated according to a predetermined rule at least once per the first unit time to generate a plurality of pieces of first partial information. In this embodiment, the MDMS 101 further includes a dividing server, and the dividing server receives power consumption information indicating power consumption from the SM 102 at least once per the first unit time and performs calculation using the power consumption indicated by the power consumption information and a value calculated according to a predetermined rule to generate a plurality of pieces of first partial information.

FIG. 12 is a diagram illustrating a configuration of the power consumption calculating system according to this embodiment. As illustrated in FIG. 12, the MDMS 101 further includes a dividing server 101c. The dividing server 101c receives power consumption information indicating power consumption from the SM 102, generates two pieces of first partial information, transmits one of the pieces of first partial information to the first storage server 101a and transmits the other piece to the second storage server 101b.

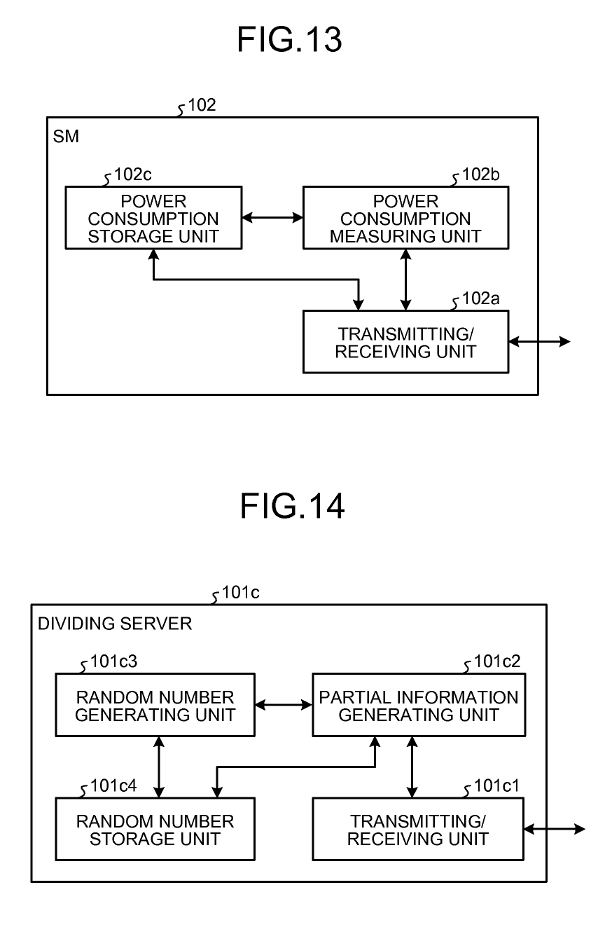

FIG. 13 is diagram illustrating a functional configuration of the SM 102 according to this embodiment. The SM 102 includes a transmitting/receiving unit 102a, a power consumption measuring unit 102b and a power consumption storage unit 102c. The functions of the power consumption measuring unit 102b and the power consumption storage unit 102c are similar to those in the first embodiment. In this embodiment, the transmitting/receiving unit 102a transmits the power consumption information indicating power consumption added up by the power consumption measuring unit 102b and home identification information to the dividing server 101c instead of transmitting the pieces of first partial information to the first storage server 101a and the second storage server 101b, respectively.

FIG. 14 is a diagram illustrating a functional configuration of the dividing server 101c. The dividing server 101c includes a transmitting/receiving unit 101c1, a partial information generating unit 101c2, a random number generating unit 101c3 and a random number storage unit 101c4. The functions of the transmitting/receiving unit 101c1 are implemented by a communication I/F of the dividing server 101c and by executing various programs stored in the main storage unit and the auxiliary storage unit by a CPU of the dividing server 101c. The functions of the partial information generating unit 101c2 and the random number generating unit 101c3 are implemented by executing various programs stored in the main storage unit and the auxiliary storage unit by the CPU of the dividing server 101c. The random number storage unit 101c4 is a storage area reserved in the auxiliary storage unit, for example, of the dividing server 101c.

The transmitting/receiving unit 101c1 is configured to control communication with other information processing devices such as the SM 102, the first storage server 101a and the second storage server 101b. In particular, in this embodiment, the transmitting/receiving unit 101c1 obtains the power consumption added up by the SM 102 by receiving the power consumption information and home identification information from the SM 102 at least once per the first unit time. In addition, the transmitting/receiving unit 101c1 transmits one of the two pieces of first partial information generated by the partial information generating unit 101c2 described later, which is the one for which the destination is determined to be the first storage server 101a, together with the home identification information to the first storage server 101a, and transmits the other piece of first partial information together with the home identification information to the second storage server 101b.

The random number generating unit 101c3 generates a random number r according to a predetermined random number generating rule under the control of the partial information generating unit 101c2, which will be described later, similarly to the random number generating unit 102e of the SM 102 described in the first embodiment. The random number storage unit 101c4 stores the random number r generated by the random number generating unit 101c3 under the control of the partial information generating unit 101c2. The random number r is deleted after being used a plurality of times by the partial information generating unit 101c2.

The partial information generating unit 101c2 performs calculation using the power consumption indicated by the power consumption information received by the transmitting/receiving unit 101c1 from the SM 102 and the random number stored in the random number storage unit 101c4 or the random number generated by the random number generating unit 101c3 at least once per the first unit time for each home to generate two pieces of first partial information. Specifically, if a random number is stored in the random number storage unit 101c4, the partial information generating unit 101c2 generates two pieces of first partial information by calculation using the random number and the power consumption indicated by the power consumption information received by the transmitting/receiving unit 101c1 from the SM 102, and deletes the random number from the random number storage unit 101c4. If no random number is stored in the random number storage unit 101c4, on the other hand, the partial information generating unit 101c2 controls the random number generating unit 101c3 to generate a random number, generates two pieces of first partial information by calculation using the random number and the power consumption indicated by the power consumption information received by the transmitting/receiving unit 101c1 from the SM 102, and then stores the random number in the random number storage unit 101c4. In this manner, for calculating two pieces of first partial information at least once per the first unit time, the partial information generating unit 101c2 uses the same random number for calculation of the pieces of partial information at each of a first period and a second period similarly to the partial information generating unit 102d of the SM 102 described in the first embodiment. The length of the first period is the first unit time. The length of the second period is the first unit time. Note that examples of equations for calculating the two pieces of first partial information are the equations (1) and (2) similarly to the above.

The partial information generating unit 101c2 also randomly determines the destination of at least one of the generated two pieces of first partial information to be the first storage server 101a or the second storage server 101b. Since the method for determining the destinations of the first partial information is similar to that for determining the destinations of the first partial information by the partial information generating unit 102d of the SM 102 in the first embodiment, the description thereof is not repeated.

Since the functional configurations of the first storage server 101a, the second storage server 101b, the EMS 103 and the billing server 104 are similar to those in the first embodiment, the description thereof is not repeated. However, the transmitting/receiving unit 101a1 of the first storage server 101a receives the first partial information from the dividing server 101c instead of the SM 102. The same applies to the transmitting/receiving unit 101b1 of the second storage server 101b.

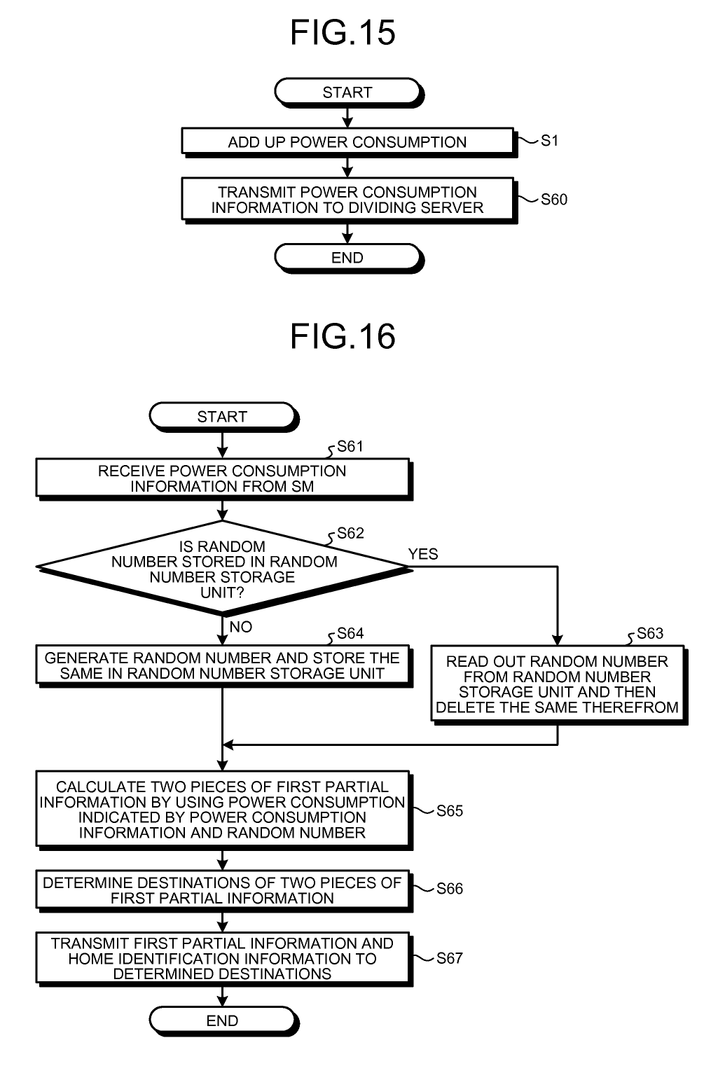

Next, procedures of processes performed by the power consumption calculating system according to this embodiment will be described. First, procedures of a process of transmitting the power consumption information by the SM 102 to the dividing server 101c will be described with reference to FIG. 15. Step S1 is the same as that in the first embodiment. Subsequently, the SM 102 transmits the power consumption information indicating the power consumption added up in step S1 and the home identification information stored in the auxiliary storage unit to the dividing server 101c (step S60).

Next, procedures of a process of receiving the power consumption information, generating two pieces of first partial information and transmitting the pieces of first partial information to the first storage server 101a and the second storage server 101b, respectively, performed by the dividing server 101c will be described with reference to FIG. 16. Upon receiving the power consumption information and the home identification information transmitted from the SM 102 in step S60 of FIG. 15 (step S61), the dividing server 101c determines whether or not a random number is stored in the random number storage unit 101c4 (step S62). If a random number is stored in the random number storage unit 101c4 (Yes in step S62), this means that a random number used for generating first partial information in previous step S65 is stored in the random number storing unit 101c4. Since the same random number as in previous step S65 is used for generating first partial information in step S65 of this time, the dividing server 101c reads out the random number from the random number storage unit 101c4, and then deletes the random number r therefrom (step S63). On the other hand, if no random number is stored in the random number storage unit 101c4 (No in step S62), the dividing server 101c generates a random number r and stores the random number r in the random number storage unit 101c4 (step S64). In this case, the random number r stored in the random number storage unit 101c4 will be used for generating first partial information in step S65 of the next time. The dividing server 101c generates two pieces of first partial information z_{i,j,1} and z_{i,j,2} by calculation of the equations (1) and (2) using the power consumption indicated by the power consumption information received in step S61 and the random number r read in step S63 or the random number generated in step S64 (step S65).

The dividing server 101c then determines the destination of each of the two pieces of partial information z_{i,j,1} and z_{i,j,2} randomly or in a predetermined manner to be the first storage server 101a or the second storage server 101b (step S66). Next, the dividing server 101c transmits the pieces of partial information z_{i,j,1} and z_{i,j,2} to the destinations determined in step S66, respectively, together with the home identification information received from the SM 102 in step S61 (step S67).

Since procedures of a process of receiving the first partial information from the dividing server 101c by the first storage server 101a are substantially the same as those described with reference to FIG. 7, detailed description thereof is not repeated. However, in step S10, the first storage server 101a receives the first partial information and the home identification information from the dividing server 101c instead of the SM 102. The same applies to the second storage server 101b.

Since procedures of a process of transmitting a transmission request by the EMS 103 to perform power control and procedures of a process of transmitting a transmission request by the billing server 104 to perform billing processing are the same as those in the first embodiment, the description thereof is not repeated.

As described above, also according to this embodiment, the total power consumption can be calculated while hiding each power consumption added up by each SM 102 at the MDMS 101 to protect the privacy.

### MODIFIED EXAMPLES

In the embodiments described above, various programs executed in at least one of the first storage server 101a, the second storage server 101b, the dividing server 101c, the SM 102, the EMS 103 and the billing server 104 may be stored on a computer system connected to a network such as the Internet, and provided by being downloaded via the network. The various programs may also be recorded on a computer readable recording medium such as a CD-ROM, a flexible disk (FD), a CD-R and a digital versatile disk (DVD) in a form of a file that can be installed or executed, and provided as a computer program product.

Moreover, in the first embodiment described above, cryptographic communication such as TLS may be used for communication between the first and second storage servers 101a and 101b and the billing server 104, communication between the first and second storage servers 101a and 101b and the EMS 103 and communication between the SM 102 and the first and second storage servers 101a and 101b so as to keep transmitted/received information secret. Furthermore, device authentication for authenticating each other may be performed in communication.

Similarly, in the second embodiment, cryptographic communication such as TLS may be used for communication between the dividing server 101c and the billing server 104, communication between the dividing server 101c and the EMS 103 and communication between the SM 102 and the dividing server 101c so as to keep transmitted/received information secret. Furthermore, device authentication for authenticating each other may be performed in communication.

Although the SM 102 transmits the pieces of first partial information to the first storage server 101a and the second storage server 101b autonomously, the function of the SM 102 is not limited thereto. Alternatively, the SM 102 may function as storage means to/from which first partial information is written or read by at least one of the first storage server 101a and the second storage server 101b. Still alternatively, the SM 102 may have a function of autonomously transmitting first partial information according to a program specified in advance or an instruction from another device.

Similarly, in the second embodiment, the SM 102 may function as storage means to/from which power consumption information is written/read by the dividing server 101c instead of autonomously transmitting power consumption information to the dividing server 101c. Still alternatively, the SM 102 may have a function of autonomously transmitting power consumption information according to a program specified in advance or an instruction from another device.

In the embodiments describe above, the EMS 103 and the billing server 104 are employed as the application server. Alternatively, a power transaction service server that manages power distribution may be employed. For example, when a unit price of power depends on total power consumption of a plurality of homes at the first unit time, the power transaction service server may receive the second partial information including the first partial information added up at every first unit time for the plurality of homes from the first storage server 101a and the second storage server 101b, respectively, restore the total power consumption of the plurality of homes at the first unit time by integrating the received second partial information, determine the power unit price by using the total power consumption and conduct power transactions, similarly to the EMS 103. In addition, a power-saving application server that performs power control on each home in cooperation with the SM 102 may be employed as the application server. In this case, instead of performing power control on each home using the power consumption of each home at the first unit time, the power-saving application server may receive the second partial information including the first partial information added up at every first unit time for a plurality of homes, restore the total power consumption of the plurality of homes at the first unit time by integrating the second partial information and perform power control on each home by using the total power consumption, similarly to the EMS 103. Alternatively, the power-saving application server may receive the third partial information within the third unit time for each home from the first storage server 101a and the second storage server 101b, respectively, restore the total power consumption within the third unit time for each home by integrating the third partial information and perform power control on each home using the total power consumption of each home, similarly to the billing server 104.

In the embodiments described above, a random number is used as a value calculated according to a predetermined rule to be used for generation of the first partial information, but the value is not limited thereto. For example, a value obtained by encrypting a predetermined value using a common key may be used instead of a random number. Moreover, although the number of times the same value for generation of the first partial information is used is two in the embodiments described above, the number of times the same value is used is not limited thereto. Furthermore, the manner in which the same value is used is not limited to the examples above. For example, in the first embodiment, the SM 102 may store a plurality of random numbers of different values used for generation of the first partial information in the random number storage unit 102f, read out the value of a random number that is not used for previous generation of the first partial information from the random number storage unit 102f and use the read value when generating the first partial information.

The same applies to the dividing server 101c in the second embodiment. In the second embodiment, the dividing server 101c may use the same value of random number for generation of the first partial information a plurality of number of times for the same SM 102, or may use the same value of random number for generation of respective pieces of first partial information for different SMs 102. In other words, the dividing server 101c may use the random number that was used for generating the first partial information previously for the same SM 102 at different power consumption times in units of the first unit time for generation of the first partial information at this time, or may use the random number that was used for generating the first partial information for a certain SM 102 for generation of the first partial information for another SM 102. Furthermore, a plurality of methods for using the same random number may be combined.

In the embodiments described above, the EMS 103 restores the total power consumption per the first unit time within the second unit time. However, the EMS 103 is not limited thereto and may restore total power consumption within the second unit time. In this case, in response to a transmission request received from the EMS 103, the first storage server 101a may read out pieces of first partial information associated with power consumption time in units of the first unit time included in the second unit time out of pieces of first partial information stored in the partial information storage unit 101a2 each in association with each of home identification information of all or some of homes belonging to a certain region, add up all read pieces of first partial information to generate second partial information, and transmit the second partial information to the EMS 103. The same applies to the second storage server 101b.

In the embodiments described above, a home energy management system may be used instead of the SM 102.

In the power consumption calculating system of the second embodiment described above, the dividing server 101c is included in the MDMS 101. However, the dividing server 101c is not limited thereto and the power consumption calculating system may have a configuration in which the dividing server 101c is not included in the MDMS 101.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirits of the inventions.

What is claimed is:

1. An information processing device comprising:
an obtaining unit that obtains a power consumption of electrical equipment at least once per unit time;
a generating unit that generates a plurality of pieces of partial information by using a first power consumption and a first value calculated according to a predetermined rule and that generates a plurality of pieces of partial information by using a second power consumption and the first value, the first power consumption being obtained at a first period, the second power consumption being obtained at a second period different from the first period, the second power consumption being obtained later than the first power consumption; and
a transmitting unit that transmits the pieces of partial information generated by using the first power consumption and the pieces of partial information generated by using the second power consumption to a plurality of different storage servers, respectively.

2. The device according to claim 1, further comprising:
a determining unit that determines destinations of all or some of the pieces of partial information to be all or some of the storage servers, wherein
the transmitting unit transmits some of the pieces of partial information to the storage servers determined by the determining unit.

3. The device according to claim 1, wherein
the electrical equipment is connected to the information processing device, and
the obtaining unit obtains the power consumption by adding up power consumptions of the electrical equipment at least once per the unit time.

4. The device according to claim 1, wherein
the obtaining unit obtains the power consumption by receiving, from a power meter to which the electrical equipment is connected, power consumption information indicating a power consumption added up by the power meter at least once per the unit time.

5. The device according to claim 4, wherein
the generating unit generates the pieces of partial information for each of power consumptions obtained from a plurality of power meters, respectively, the generating unit generating a plurality of pieces of partial information by using the first power consumption obtained from a first power meter and the first value, and generating a plurality of new pieces of partial information by using the second power consumption newly obtained from the first power meter and the first value.

6. The device according to claim 4, wherein
the generating unit generates the pieces of partial information for each of power consumptions obtained from a plurality of power meters, respectively, the generating unit generating a plurality of pieces of partial information by using the first power consumption obtained from a first power meter and the first value, and generating a plurality of new pieces of partial information by using the second power consumption newly obtained from a second power meter and the first value.

7. The device according to claim 1, further comprising:
a calculating unit that calculates the first value according to the predetermined rule; and
a storage unit that stores the first value therein, wherein
the generating unit generates the pieces of partial information by using the first power consumption and the first value calculated by the calculating unit or the first value stored in the storage unit.

8. A power consumption calculating system including a plurality of power meters that add up power consumptions of electrical equipment, a plurality of storage servers, and an energy management system, the power consumption calculating system comprising:
an obtaining unit that obtains power consumptions added up by the power meters at least once per unit time;
a first generating unit that generates a plurality of pieces of first partial information by using a first power consumption and a first value calculated according to a predetermined rule and that generates a plurality of pieces of first partial information by using a second power consumption and the first value, the first power consumption being obtained at a first period, the second power consumption being obtained at a second period different from the first period, the second power consumption being obtained later than the first power consumption; and
a first transmitting unit that transmits the pieces of first partial information generated by using the first power consumption and the pieces of first partial information generated by using the second power consumption to the different storage servers, respectively, wherein
the storage servers each include:
a first receiving unit that receives a piece of the first partial information;
a storage unit that stores the piece of first partial information received by the receiving unit;
a second receiving unit that receives first transmission request requesting transmission of a first total within a second unit time of the power consumptions added up by the power meters;
a second generating unit that generates a piece of second partial information by using the piece of first partial information stored in the storage unit in response to the first transmission request; and
a second transmitting unit that transmits the piece of second partial information to the energy management system,
the energy management system includes:
a third transmitting unit that transmits the first transmission request to the storage servers;
a third receiving unit that receives the pieces of second partial information from the storage servers; and
a restoring unit that restores the first total by using the pieces of the second partial information.

9. A program product having a computer readable medium including programmed instructions, wherein the instructions, when executed by a computer, cause the computer to perform:
obtaining a power consumption of electrical equipment at least once per unit time;
generating a plurality of pieces of partial information by using a first power consumption and a first value calculated according to a predetermined rule and generating a plurality of pieces of partial information by using a second power consumption and the first value, the first power consumption being obtained at a first period, the second power consumption being obtained at a second period different from the first period, the second power consumption being obtained later than the first power consumption; and
transmitting the pieces of partial information generated by using the first power consumption unit and the pieces of partial information generated by using the second power consumption unit to a plurality of different storage servers, respectively.
